(19) United States
(12) Patent Application Publication
(10) Pub. No.: US 2025/0273454 A1
(43) Pub. Date: Aug. 28, 2025

(54) MICROWAVE ASSISTED PASSIVATION LAYER REMOVAL

(71) Applicant: Applied Materials, Inc., Santa Clara, CA (US)

(72) Inventors: Jiajie CEN, Santa Clara, CA (US); Yong Jin KIM, Santa Clara, CA (US); Carmen Leal CERVANTES, Santa Clara, CA (US); Yoon Ah SHIN, Santa Clara, CA (US); Zhiyuan WU, San Jose, CA (US); Bencherki MEBARKI, Santa Clara, CA (US); Kevin KASHEFI, Dublin, CA (US); Joung Joo LEE, San Jose, CA (US); Xianmin TANG, San Jose, CA (US)

(21) Appl. No.: 18/590,111

(22) Filed: Feb. 28, 2024

(51) Int. Cl. H01L 21/02; H01L 21/768

(52) U.S. Cl. CPC H01L 21/02068; H01L 21/76843

(57) ABSTRACT

A method of processing a substrate, includes performing a preclean process to form an exposed surface of a conductive layer within a via formed in a dielectric layer formed over the conductive layer, forming a passivation layer over the exposed surface of the conductive layer, and removing the passivation layer using a microwave assisted process.

### BACKGROUND

### Field

Embodiments described herein generally relate to a semiconductor device fabrication process. More specifically, embodiments of the present disclosure relate to microwave sources used in one or more semiconductor device containing substrate processing steps, such as removing a passivation layer.

### Description of the Related Art

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

In fabrication of an integrated circuit, middle-end-of-line (MEOL) and back-end-of-line (BEOL) stages may include forming gate regions of transistors and local interconnect layers. Typically when depositing a barrier layer during MEOL and BEOL stages on sidewalls of vias and or trenches formed in interconnect structures, exposed portions of underlying conductive layers are protected by a passivation layer to prevent the barrier layer from covering the exposed conductive layer. Passivation layers are commonly removed by use of a capacitively coupled plasma (CCP) processing technique. However CCP removal techniques cause low-k carbon loss and damage along with hydrogen plasma reduced damages.

There is a need in the art for a method of removing one or more passivation layers without damaging the underlying layers formed on a substrate.

### SUMMARY

According to one or more embodiments, a method of processing a substrate, includes performing a preclean process to form an exposed surface of a conductive layer within a via formed in a dielectric layer formed over the conductive layer, forming a passivation layer over the exposed surface of the conductive layer, and removing the passivation layer using a microwave assisted process.

According to one or more embodiments, a method of processing a substrate includes performing a preclean process to form an exposed surface of a conductive layer within a via formed in a dielectric layer formed over the conductive layer, forming a passivation layer over the exposed surface of the conductive layer, and removing the passivation layer using a microwave assisted process, the microwave assisted process including flowing a process gas into a processing chamber, and delivering microwave energy to the processing gas, wherein delivering the microwave energy to the process gas does not generate a plasma in the processing chamber.

According to one or more embodiments, a method of processing a substrate includes performing a preclean process to form an exposed surface of a conductive layer within a via formed in a dielectric layer formed over the conductive layer, forming a passivation layer over the exposed surface of the conductive layer, forming a barrier layer on sidewalls of the via, and removing the passivation layer using a microwave assisted process, the microwave assisted process includes flowing a process gas that comprises hydrogen into a processing chamber, and delivering microwave energy to the processing gas, wherein delivering the microwave energy to the process gas does not generate a plasma in the processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a schematic top view of a multi-chamber processing system, according to embodiments.

FIG. 2 is a process flow diagram of a method for removal of a passivation layer from an interconnect structure, according to one or more embodiments.

FIGS. 3A-3D are cross-sectional views of a portion of the interconnect structure corresponding to various states of the method 200, according to one or more embodiments.

FIG. 4A is a schematic of a processing chamber that includes a microwave source, according to one or more embodiments.

FIG. 4B is a schematic of a solid state microwave emission module, according to one or more embodiments.

FIG. 4C is a perspective view illustration of a source array for a microwave source, according to one or more embodiments.

FIG. 4D is a cross-sectional illustration of a processing chamber for processing a substrate, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In fabrication of an integrated circuit, middle-end-of-line (MEOL) and back-end-of-line (BEOL) stages may include forming gate regions of transistors and local interconnect layers. Typically when depositing a barrier layer during MEOL and BEOL stages on sidewalls of vias and or trenches formed in interconnect structures, exposed portions of underlying conductive layers are protected by a passivation layer to prevent the barrier layer from covering the conductive layer. The passivation layer can include a self-assembled monolayer (SAM). After depositing the barrier layer the SAM is removed to re-expose the portions of the conductive layer. SAMs are commonly removed using capacitively coupled plasma (CCP) techniques. However CCP removal techniques cause ion bombardment related damage to the low-k materials disposed beneath the SAM.

Embodiments of the present disclosure generally relate to using a non-plasma microwave assisted process to remove the passivation layer within interconnect structures with reduced amount of low-k carbon loss and damage, and also preventing a significant amount of hydrogen plasma damage.

### Processing System Example

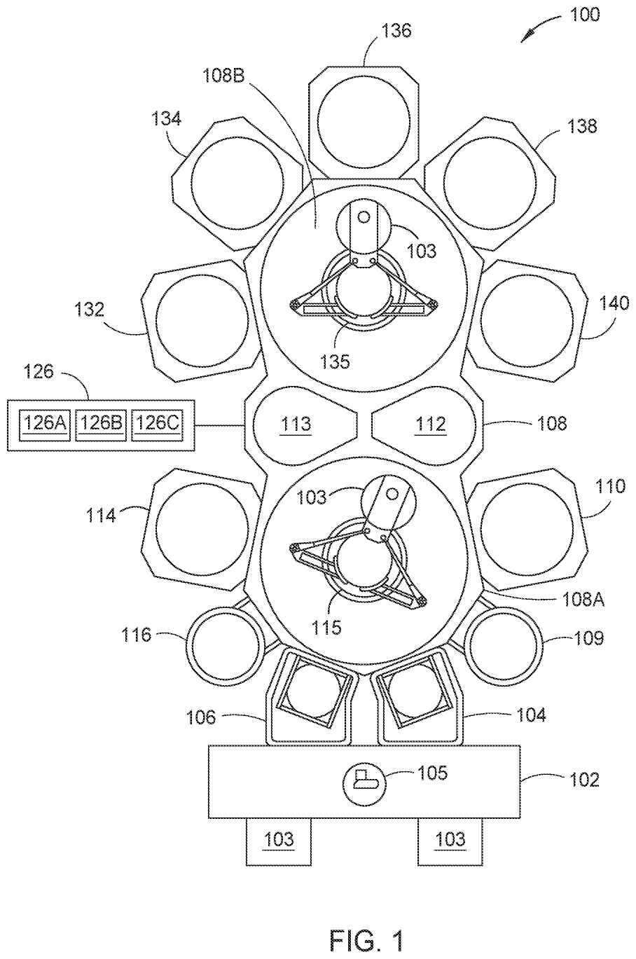

FIG. 1 illustrates a schematic representation of a processing system 100 for use with one or more embodiments of the disclosure. As detailed below, substrates in the processing system 100 may be processed in and transferred between the various chambers without exposing the substrates to an ambient environment exterior to the processing system 100 (for example, an atmospheric ambient environment such as may be present in a fab). For example, the substrates may be processed in and transferred between the various chambers maintained at a low pressure (for example, less than or equal to about 300 Torr) or sub-atmospheric pressure, such as a vacuum environment, without breaking the reduced relative pressure or vacuum environment among various processes performed on the substrates in the processing system 100. Accordingly, the processing system 100 may provide for an integrated solution for some processing of substrates.

FIG. 1 is a schematic top view of the substrate processing system 100, according to one or more embodiments. The substrate processing system 100 generally includes an equipment front-end module (EFEM) 102 for loading substrates into the processing system 100, a first load lock chamber 104 coupled to the EFEM 102, a second load lock chamber 106 coupled to the EFEM 102, a transfer chamber 108 coupled to the first load lock chamber 104 and the second load lock chamber 106, and a plurality of other chambers coupled to the transfer chamber 108 as described in detail below. The EFEM 102 generally includes one or more robots 105 that are configured to transfer substrates from front opening unified pods (FOUPs) 103 to at least one of the first load lock chamber 104 or the second load lock chamber 106. Proceeding counterclockwise around the transfer chamber 108 from a buffer portion 108A of the transfer chamber 108, the processing system 100 includes a first dedicated degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates to each of the load lock chambers 104, 106, the degas chambers 109, 116, the pre-clean chambers 110, 114 and the pass-through chambers 112, 113.

A back-end portion 108B of the transfer chamber 108 includes a second robot 135 that is configured to transfer substrates to each of the pass-through chambers 112, 113 and the processing chambers coupled to the back-end portion 108B of the processing system 100. The processing chambers can include a first processing chamber 132, a second processing chamber 134, a third processing chamber 136, a fourth processing chamber 138 and a fifth process chamber 140. In general, the processing chambers 132, 134, 136, 138, 140 can include at least one of an atomic layer deposition (ALD) chamber, chemical vapor deposition (CVD) chamber, physical vapor deposition (PVD) chamber, etch chamber, degas chamber, an anneal chamber, or other type of semiconductor substrate processing chamber. In some embodiments, one or more of the processing chambers 132, 134, 136, 138, 140 is a PVD chamber. In some examples, the processing chamber 110 may be capable of performing an etch process, the processing chamber 114 may be capable of performing a cleaning process or an annealing process, and the processing chambers 132, 134, 136, 138, 140 may be capable of performing respective CVD or ALD deposition processes. In one example, the processing chambers 132, 134, 136, 138, or 140 may be Volta™ CVD/ALD chambers, or Encore™ PVD chambers available from Applied Materials of Santa Clara, California.

The buffer portion 108A and back-end portion 108B of the transfer chamber 108 and each chamber coupled to the transfer chamber 108 may be maintained at a vacuum state. As used herein, the term “vacuum” may refer to pressures less than 760 Torr, and will typically be maintained at pressures near 10⁻⁵ Torr (that is, ˜10⁻³ Pa). However, some high-vacuum systems may operate below near 10⁻⁷ Torr (that is, ˜10⁻⁵ Pa). In certain embodiments, the vacuum is created using a rough pump and/or a turbomolecular pump coupled to the transfer chamber 108 and to each of the one or more process chambers (for example, process chambers 109-140). However, other types of vacuum pumps are also contemplated.

A system controller 126, such as a programmable computer, is coupled to the processing system 100 for controlling one or more of the components therein. For example, the system controller 126 may control the operation of one or more of the processing chambers, such as processing chambers 132, 134, 136, 138, 140. In operation, the system controller 126 enables data acquisition and feedback from the respective components to coordinate processing in the processing system 100.

The system controller 126 includes a programmable central processing unit (CPU) 126A, which is operable with a memory 126B (for example, non-volatile memory) and support circuits 126C. The support circuits 126C (for example, cache, clock circuits, input/output subsystems, power supplies, etc., and combinations thereof) are conventionally coupled to the CPU 126A and coupled to the various components within the processing system 100.

In some embodiments, the CPU 126A is one of any form of general purpose computer processor used in an industrial setting, such as a programmable logic controller (PLC), for controlling various monitoring system component and sub-processors. The memory 126B, coupled to the CPU 126A, is non-transitory and is typically one or more of readily available memory such as random access memory (RAM), read only memory (ROM), floppy disk drive, hard disk, or any other form of digital storage, local or remote.

Herein, the memory 126B is in the form of a computer-readable storage media containing instructions (for example, non-volatile memory), that when executed by the CPU 126A, facilitates the operation of the processing system 100. The instructions in the memory 126B are in the form of a program product such as a program that implements the methods of the present disclosure (for example, middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (for example, read-only memory devices within a computer such as CD-ROM disks readable by a CD-ROM drive, flash memory, ROM chips or any type of solid-state non-volatile semiconductor memory) on which information is permanently stored; and (ii) writable storage media (for example, floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. The various methods disclosed herein may generally be implemented under the control of the CPU 126A by the CPU 126A executing computer instruction code stored in the memory 126B (or in memory of a particular processing chamber) as, for example, a software routine. When the computer instruction code is executed by the CPU 126A, the CPU 126A controls the chambers to perform processes in accordance with the various methods.

As will be described further below, in one or more embodiments of the substrate processing sequence described herein, all of the processes are performed under vacuum within the processing system 100.

### Substrate Processing Sequences

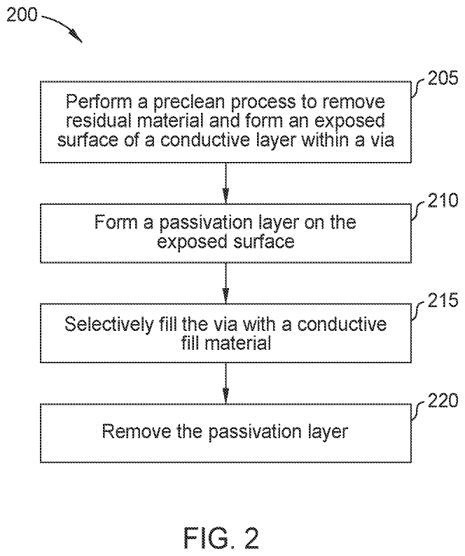

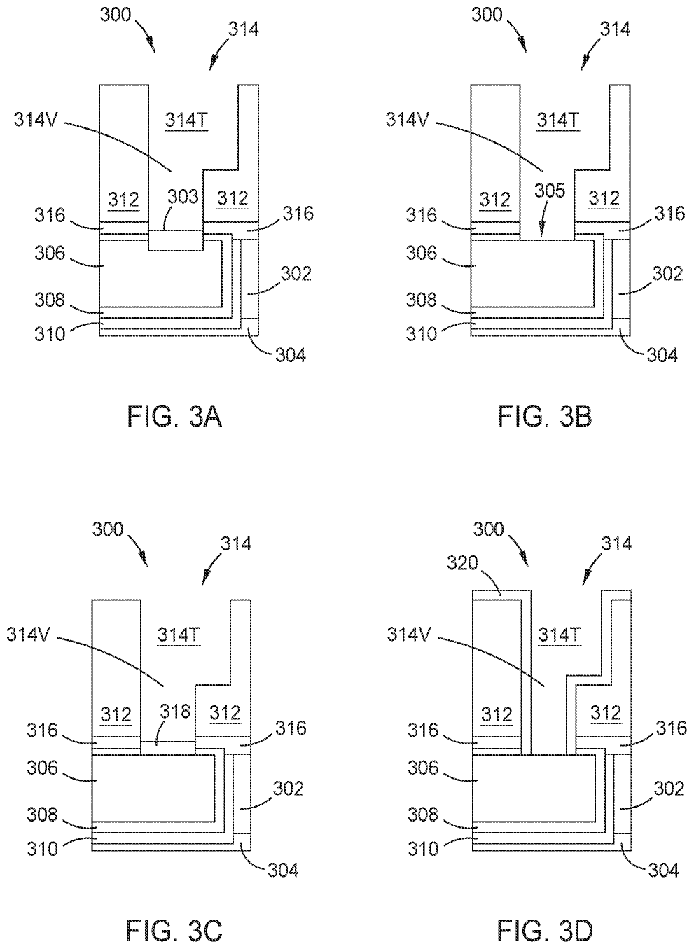

FIG. 2 depicts a process flow diagram of a method 200 for removal of a passivation layer from an interconnect structure, such as an interconnect structure 300 formed on a substrate according to one or more embodiments as depicted in FIGS. 3A-3D. FIGS. 3A-3D are cross-sectional views of a portion of the interconnect structure 300 corresponding to various states of the method 200. It should be understood that FIGS. 3A-3D illustrate only partial schematic views of the interconnect structure 300, and the interconnect structure 300 may contain any number of transistor sections and additional materials having aspects as illustrated in the figures. It should also be noted that although the method illustrated in FIG. 2 is described sequentially, other process sequences that include one or more operations that have been omitted and/or added, and/or has been rearranged in another desirable order, fall within the scope of the embodiments of the disclosure provided herein.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

As shown in FIG. 3A, the interconnect structure 300 includes a first dielectric layer 302 formed on a substrate (not shown). The first dielectric layer 302 may be formed of a dielectric material, such as low k dielectric (SiCOH), silicon dioxide (SiO₂), silicon nitride (Si₃N₄), silicon carbide (SiC), aluminum oxide (Al₂O₃), or aluminum nitride (AlN). A first etch stop layer 304 may be disposed between the first dielectric layer 302 and the substrate. The interconnect structure 300 further includes a conductive layer 306 embedded within the first dielectric layer 302 and separated from the first dielectric layer 302 by a liner layer 308 and a barrier layer 310. The conductive layer 306 may be formed of copper (Cu), cobalt (Co), molybdenum (Mo), tungsten (W), or ruthenium (Ru). The liner layer 308 may be formed of ruthenium (Ru) and cobalt (Co), or RuCo. The barrier layer 310 may be formed of tantalum nitride (TaN) or doped tantalum nitride (TaN). The interconnect structure 300 further includes a second dielectric layer 312, having one or more features 314, such as a via 314V and a trench 314T formed therein, over the first dielectric layer 302 and the conductive layer 306. The second dielectric layer 312 may be formed of the same material as the first dielectric layer 302, such as low k dielectric (SiCOH), silicon dioxide (SiO₂), silicon nitride (Si₃N₄), silicon carbide (SIC), aluminum oxide (Al₂O₃), or aluminum nitride (AlN). In another embodiment, the second dielectric layer 312 may be formed of a different material from the first dielectric layer 302, while maintaining the same low-k properties. A second etch stop layer 316 may be disposed between the second dielectric layer 312 and the first dielectric layer 302. In one example, during formation of the via 314V and the trench 314T, a residual material 303 may be formed over the conductive layer 306 within the via 314V. In one example, the residual material 303 includes halogen containing materials and/or any metal oxide containing materials from the surface of the substrate by use of a low temperature non-plasma microwave assisted process.

The method 200 begins with block 205, in which a preclean process is performed on the substrate to remove the residual material 303, forming an exposed surface 305 of the conductive layer 306 within the via 314V, as shown in FIG. 3B. In some embodiments, the preclean process includes the delivery of a process gas (e.g., hydrogen containing gas) into a processing region of a process chamber (e.g., chamber 110, 114) and delivering microwave energy to the process gas to excite the process gas and remove the halogen containing and/or metal oxide containing contaminants from the substrate surface. It is desirable to avoid forming a plasma over the surface of the substrate during block 205 to avoid the ions that would be generated in the plasma from causing damage to the material layers found on the substrate surface. The microwave delivery process can include delivering between 1 to 400 Watts of microwave energy at a temperature between 25 and 450° C. while the chamber is maintained at a pressure of between 10 and 300 mTorr and a flow rate of between 1 and 1000 sccm of molecular hydrogen (H₂) is flowed in the chamber. In an embodiment, the high-frequency electromagnetic radiation provided from a microwave source may have a frequency between approximately 300 MHz and 1000 GHz, such as between approximately 1 GHz and 300 GHz.

At block 210 a deposition process is performed on the substrate to form a passivation layer 318 selectively on the exposed surface 305 of the conductive layer 306 within the via 314V, as shown in FIG. 3C. The deposition process may be performed in a processing chamber, such as the processing chamber 132, 134, 136, 138, or 140 shown in FIG. 1.

The passivation layer 318 may be formed of a self-assembled monolayer (SAM) of organic molecules. In one example the SAM may comprise any suitable material including, but not limited to carbon, hydrogen, or combinations thereof. In one example, the SAM may be formed using a soaking process. In the soaking process, the interconnect structure 300 is soaked in a gas precursor including an unsaturated hydrocarbon, at a temperature of less than about 450° C. and a pressure of less than about 80 Torr for a time duration of greater than about 10 seconds, with a flow rate of the precursor of between 50 sccm and about 600 sccm. In some embodiments, a liquid precursor is used in the soaking process. In the soaking process, organic molecules in the precursor are absorbed only on a metal surface, such as the exposed surface 305 of the conductive layer 306. The passivation layer 318 may act as a block layer that suppresses nucleation or growth of a subsequent material deposition thereon.

At block 215, a selective deposition process is performed to form a barrier layer 320 on inner sidewalls of the via 314V and the trench 314T, and not on the passivation layer 318, as shown in FIG. 3D The selective deposition process may include an ALD process in a processing chamber, such as the processing chambers shown in FIG. 1.

The barrier layer 320 may be formed of tantalum nitride (TaN) or doped tantalum nitride (TaN), metal doped TaN, titanium nitride (TiN), tungsten nitride (WN), or tungsten nitride carbide (WCN). The selectivity in the selective deposition process may arise from differences in nucleation of the barrier layer 320 on exposed surfaces of the second dielectric layer 312 (e.g., silicon dioxide (SiO₂) or silicon nitride (Si₃N₄)) and on the passivation layer 318. In some embodiments, the barrier layer 320 is deposited by sequentially exposing the interconnect structure 300 to a metal precursor and a reactant. In one example, the barrier layer 320 may include additional layers. For example, the barrier layer may include a liner layer that comprises be ruthenium (Ru), cobalt (Co), molybdenum (Mo), iridium (IR), osmium (Os), rhenium (Re), rhodium (Rh) or tungsten (W).

At block 220, a removal process is performed to remove the passivation layer 318 from the surface of the conductive layer 306, as shown in FIG. 3D. In one example, the removal process may include use of a low temperature non-plasma microwave assisted process. In some other embodiments, the removal process includes the delivery of a process gas (e.g., hydrogen containing gas) to a processing region of a process chamber and delivering microwave energy to the process gas to excite the process gas and remove the halogen containing and/or metal oxide containing contaminants from the substrate surface. It is desirable to avoid forming a plasma over the surface of the substrate during block 220 to avoid the ions that would be generated in the plasma from causing damage to the material layers found on the substrate surface. The microwave delivery process can include delivering 125 (1-1000) Watts of microwave energy while the chamber is maintained at a pressure of between 20 mTorr and 60 mTorr and a flow rate of between 1 and 1000 sccm of molecular hydrogen (H₂) is flowed in the chamber. In an embodiment, the high-frequency electromagnetic radiation provided from a microwave source may have a frequency between approximately 300 MHz and 1000 GHz, such as between approximately 1 GHz and 300 GHz.

### Processing Chamber Example

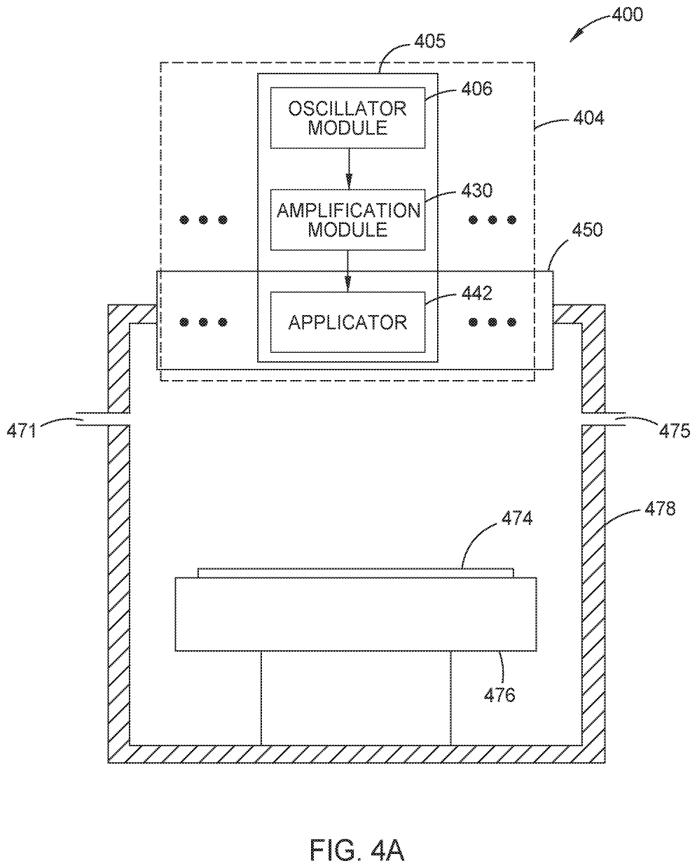

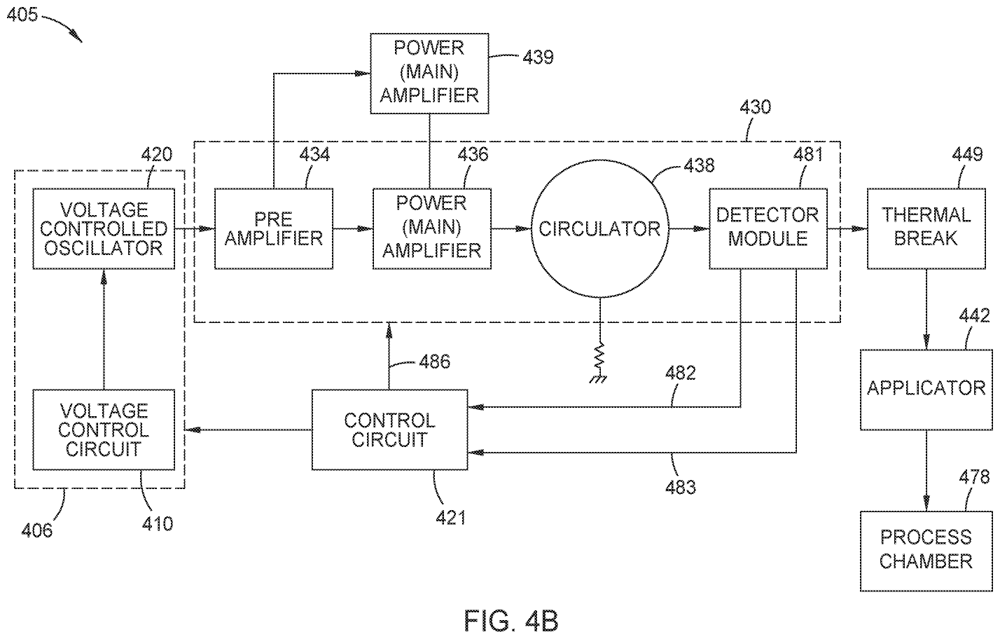

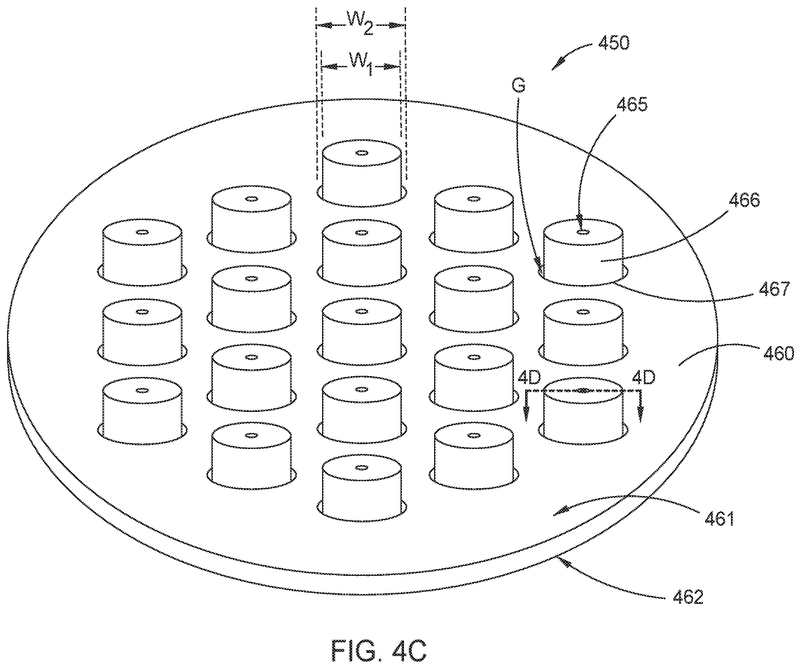

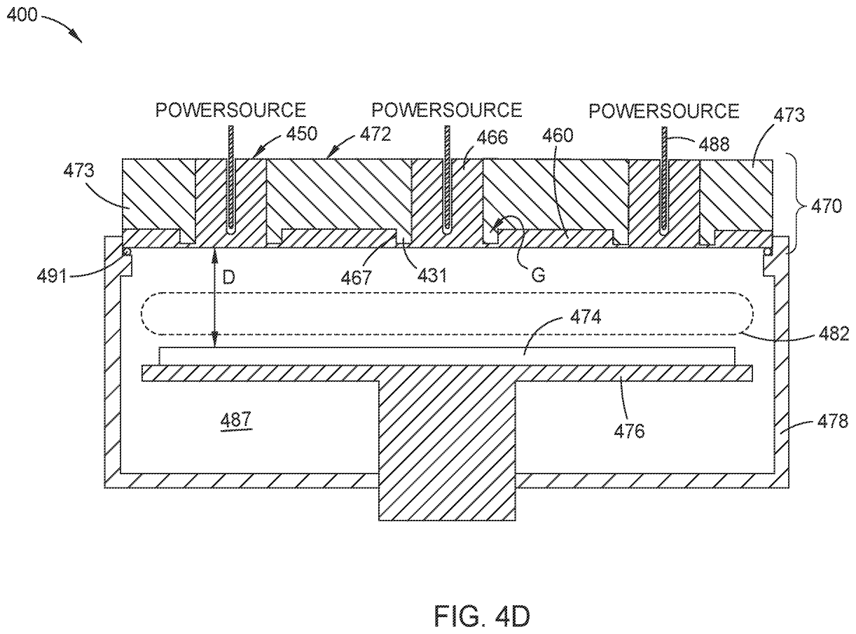

Referring now to FIGS. 4A-4D, a series of illustrations depicting an example of a microwave processing tool 400 is shown, in accordance with an embodiment. The microwave processing tool 400 is configured to deliver microwave energy to a processing region of the process chamber to perform removal of a passivation layer, such as passivation layer 318 (FIG. 3C) from an interconnect structure 300 formed on a substrate.

Referring now to FIG. 4A, a cross-sectional illustration of a microwave processing tool 400) is shown, according to one or more embodiments. In some embodiments, the microwave processing tool 400 may be a processing tool suitable for any type of processing operation that requires the delivery of microwave energy. In some embodiments, one or more of the chambers 110 and 114, or even chambers 132-140, may include the microwave processing tool 400. The processing tool may emit high-frequency electromagnetic radiation in the form of microwave energy. In some embodiments, “High-frequency” may refer to frequencies between 300 MHz and 1000 GHz.

Generally, embodiments include a microwave processing tool 400 that includes a chamber 478. In microwave processing tool 400, the chamber 478 may be a vacuum chamber. A vacuum chamber may include a pump (not shown) for removing gases from the chamber to provide the desired vacuum. Additional embodiments may include a chamber 478 that includes one or more gas lines 471 for providing processing gases into the chamber 478 and exhaust lines 475 for removing byproducts from the chamber 478. While not shown, it is to be appreciated that gas may also be injected into the chamber 478 through a source array 450 (e.g., as a showerhead) for evenly distributing the processing gases over a substrate 474.

In an embodiment, the substrate 474 may be supported on a chuck 476. For example, the chuck 476 may be any suitable chuck, such as an electrostatic chuck. The chuck 476 may also include cooling lines and/or a heater to provide temperature control to the substrate 474 during processing. Due to the modular configuration of the high-frequency emission modules described herein, embodiments allow for the microwave processing tool 400 to accommodate any sized substrate 474. For example, the substrate 474 may be a semiconductor wafer (e.g., 200 mm, 300 mm, 450 mm, or larger). Alternative embodiments also include substrates 474 other than semiconductor wafers. For example, embodiments may include a microwave processing tool 400 configured for processing glass substrates, (e.g., for display technologies).

According to an embodiment, the microwave processing tool 400 includes a modular high-frequency emission source 404. The modular high-frequency emission source 404 may comprise an array of high-frequency emission modules 405. In an embodiment, each high-frequency emission module 405 may include an oscillator module 406, an amplification module 430, and an applicator 442. As shown, the applicators 442 are schematically shown as being integrated into the source array 450.

In an embodiment, the oscillator module 406 and the amplification module 430 may comprise electrical components that are solid state electrical components. In an embodiment, each of the plurality of oscillator modules 406 may be communicatively coupled to different amplification modules 430. For example, each oscillator module 406 may be electrically coupled to a single amplification module 430. In an embodiment, the plurality of oscillator modules 406 may generate incoherent electromagnetic radiation. Accordingly, the electromagnetic radiation induced in the chamber 478 will not interact in a manner that results in an undesirable interference pattern.

In an embodiment, each oscillator module 406 generates high frequency electromagnetic radiation that is transmitted to the amplification module 430. After processing by the amplification module 430, the electromagnetic radiation is transmitted to the applicator 442. In an embodiment, the applicators 442 each emit electromagnetic radiation into the chamber 478. In some embodiments, the applicators 442 couple the electromagnetic radiation to the processing gases in the chamber 478 to provide energy thereto, without forming a plasma.

Referring now to FIG. 4B, a schematic of a solid state high-frequency emission module 405 is shown, in accordance with an embodiment. In an embodiment, the high-frequency emission module 405 comprises the oscillator module 406. The oscillator module 406 may include a voltage control circuit 410 for providing an input voltage to a voltage controlled oscillator 420 in order to produce high-frequency electromagnetic radiation at a desired frequency. The voltage controlled oscillator 420 is an electronic oscillator whose oscillation frequency is controlled by the input voltage. According to an embodiment, the input voltage from the voltage control circuit 410 results in the voltage controlled oscillator 420 oscillating at a desired frequency.

According to an embodiment, the electromagnetic radiation is transmitted from the voltage controlled oscillator 420 to the amplification module 430. The amplification module 430 may include a driver/pre-amplifier 434, and a main power amplifier 436 that are each coupled to a power supply 439. According to an embodiment, the amplification module 430 may operate in a pulse mode. For example, the amplification module 430 may have a duty cycle between 1% and 99%. In a more particular embodiment, the amplification module 430 may have a duty cycle between approximately 15% and 50%.

In an embodiment, the electromagnetic radiation may be transmitted to a thermal break 449 and the applicator 442 after being processed by the amplification module 430. However, part of the power transmitted to the thermal break 449 may be reflected back due to the mismatch in the output impedance. Accordingly, some embodiments include a detector module 481 that allows for a level of forward power 483 and reflected power 482 to be sensed and fed back to a control circuit module 421. It is to be appreciated that the detector module 481 may be located at one or more different locations in the system (e.g., between a circulator 438 and the thermal break 449). In an embodiment, the control circuit module 421 interprets the forward power 483 and the reflected power 482, and determines the level for a control signal 485 that is communicatively coupled to the oscillator module 406 and the level for a control signal 486 that is communicatively coupled to the amplification module 430. In an embodiment, the control signal 485 adjusts the oscillator module 406 to optimize the high-frequency radiation coupled to the amplification module 430. In an embodiment, control signal 486 adjusts the amplification module 430 to optimize the output power coupled to the applicator 442 through the thermal break 449. In an embodiment, the feedback control of the oscillator module 406 and the amplification module 430, in addition to the tailoring of the impedance matching in the thermal break 449, may allow for the level of the reflected power to be less than approximately 5% of the forward power. In some embodiments, the feedback control of the oscillator module 406 and the amplification module 430 may allow for the level of the reflected power to be less than approximately 2% of the forward power.

Accordingly, embodiments allow for an increased percentage of the forward power to be coupled into the chamber 478, and increases the available power provided to the process gases disposed within the processing volume. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator.

Referring now to FIG. 4C, a perspective view illustration of the source array 450 is shown, in accordance with an embodiment. In an embodiment, the source array 450 comprises a dielectric plate 460. A plurality of cavities 467 are disposed into a first surface 461 of the dielectric plate 460. The cavities 467 do not pass through to a second surface 462 of the dielectric plate 460. The source array 450 may further include a plurality of dielectric resonators 466. Each of the dielectric resonators 466 may be in a different one of the cavities 467. Each of the dielectric resonators 466 may comprise a hole 465 in the axial center of the dielectric resonator 466.

In an embodiment, the dielectric resonators 466 may have a first width W1, and the cavities 467 may have a second width W2. The first width W1 of the dielectric resonator 466 is smaller than the second width W2 of the cavities 467. The difference in the widths provides a gap G between a sidewall of the dielectric resonators 466 and a sidewall of the cavity 467. In the illustrated embodiment, each of the dielectric resonators 466 are shown as having a uniform width W1. However, it is to be appreciated that not all dielectric resonators 466 of a source array 450 need to have the same dimensions.

Referring now to FIG. 4D, a cross-sectional illustration of a microwave processing tool 400 that includes an assembly 470 is shown, in accordance with an embodiment. In an embodiment, the processing tool comprises the chamber 478 that is sealed by the assembly 470. For example, the assembly 470 may rest against one or more O-rings 491 to provide a vacuum seal to an interior volume 487 of the chamber 478. In other embodiments, the assembly 470 may interface with the chamber 478. That is, the assembly 470 may be part of a lid that seals the chamber 478. In an embodiment, the microwave processing tool 400 may comprise a plurality of processing volumes (which may be fluidically coupled together), with each processing volume having a different assembly 470. In an embodiment, the chuck 476 or the like may support the substrate 474. The substrate 474 may be a distance D from the assembly 470. In an embodiment, the interior volume 487 may be suitable for delivering microwave energy to a process gas disposed within the chamber 478. That is, the chamber 478 may be a vacuum chamber.

In an embodiment, the assembly 470 comprises the source array 450 and a housing 472. The source array 450 may comprise the dielectric plate 460 and the plurality of dielectric resonators 466 extending up from the dielectric plate 460. Cavities 467 into the dielectric plate 460 may surround each of the dielectric resonators 466. Sidewalls of the cavity 467 are separated from the sidewall of the dielectric resonator 466 by the gap G. The dielectric plate 460 and the dielectric resonators 466 of the source array 450 may be a monolithic structure (as shown in FIG. 4D), or the dielectric plate 460 and the dielectric resonators 466 may be discrete components.

The housing 472 includes rings 431 that fit into the gaps G. In an embodiment, the rings 431 and the conductive body 473 of the housing 472 are a monolithic structure (as shown in FIG. 4D), or the conductive body 473 and the rings 431 may be discrete components. The housing 472 may having openings sized to receive the dielectric resonators 466. In an embodiment, monopole antennas 488 may extend into holes in the dielectric resonators 466. The monopole antennas 488 are each electrically coupled to power sources (e.g., high-frequency emission modules 405).

While the foregoing is directed to embodiments of the present disclosure, other and further embodiments of the disclosure may be devised without departing from the basic scope thereof, and the scope thereof is determined by the claims that follow.

What is claimed is:

1. A method of processing a substrate, comprising:
performing a preclean process to form an exposed surface of a conductive layer within a via formed in a dielectric layer formed over the conductive layer;
forming a passivation layer over the exposed surface of the conductive layer; and
removing the passivation layer using a microwave assisted process.

2. The method of claim 1, wherein the microwave assisted process is a non-plasma microwave assisted process.

3. The method of claim 1, wherein the microwave assisted process comprises delivering a process gas to a processing region of a process chamber and delivering microwave energy to the process gas to excite the process gas.

4. The method of claim 3, wherein the process gas is a hydrogen containing gas.

5. The method of claim 1, where in the passivation layer is a self-assembled monolayer (SAM).

6. The method of claim 5, wherein the SAM comprises carbon, hydrogen, or combinations thereof.

7. The method of claim 1, further comprising selectively depositing a barrier layer on inner sidewalls of the via.

8. The method of claim 3, wherein the microwave energy is delivered at a power between 50 to 200 Watts at a temperature between 10° and 350° C. and a flow rate of the processing gas is between 5 and 50 sccm.

9. The method of claim 7, wherein the barrier layer comprises tantalum nitride (TaN) or doped tantalum nitride (TaN), metal doped TaN, titanium nitride (TiN), tungsten nitride (WN), or tungsten nitride carbide (WCN).

10. A method of processing a substrate comprising:
performing a preclean process to form an exposed surface of a conductive layer within a via formed in a dielectric layer formed over the conductive layer;
forming a passivation layer over the exposed surface of the conductive layer; and
removing the passivation layer using a microwave assisted process, the microwave assisted process comprising:
flowing a process gas into a processing chamber; and
delivering microwave energy to the processing gas, wherein delivering the microwave energy to the process gas does not generate a plasma in the processing chamber.

11. The method of claim 10, wherein the processing gas comprises hydrogen.

12. The method of claim 10, where in the passivation layer is a self-assembled monolayer (SAM).

13. The method of claim 12, wherein the SAM comprises carbon, hydrogen, or combinations thereof.

14. The method of claim 10, further comprising selectively depositing a barrier layer on inner sidewalls of the via.

15. The method of claim 14, wherein the microwave energy is delivered at a power between 50 to 200 Watts at a temperature between 10° and 350° C. and a flow rate of the processing gas is between 5 and 50 sccm.

16. The method of claim 14, wherein the barrier layer comprises tantalum nitride (TaN) or doped tantalum nitride (TaN), metal doped TaN, titanium nitride (TiN), tungsten nitride (WN), or tungsten nitride carbide (WCN).

17. A method of processing a substrate comprising:
performing a preclean process to form an exposed surface of a conductive layer within a via formed in a dielectric layer formed over the conductive layer;
forming a passivation layer over the exposed surface of the conductive layer;
forming a barrier layer on sidewalls of the via; and
removing the passivation layer using a microwave assisted process, the microwave assisted process comprising:
flowing a process gas that comprises hydrogen into a processing chamber; and
delivering microwave energy to the processing gas, wherein delivering the microwave energy to the process gas does not generate a plasma in the processing chamber.

18. The method of claim 17, where in the passivation layer is a self-assembled monolayer (SAM).

19. The method of claim 18, wherein the SAM comprises carbon, hydrogen, or combinations thereof.

20. The method of claim 17, wherein the microwave energy is delivered at a power between 50 to 200 Watts at a temperature between 10° and 350° C. and a flow rate of the process gas is between 5 and 50 sccm.
